(19) United States
(12) Patent Application Publication
(10) Pub. No.: US 2011/0193598 A1
(43) Pub. Date: Aug. 11, 2011

(54) EFFICIENT RETIMER FOR CLOCK DIVIDERS

(75) Inventors: Bhavesh G. Bhakta, Richardson, TX (US); Charles M. Branch, Dallas, TX (US)

(73) Assignee: Texas Instruments Incorporated, Dallas, TX (US)

(21) Appl. No.: 12/704,192

(22) Filed: Feb. 11, 2010

(51) Int. Cl. H03L 7/00

(52) U.S. Cl. 327/141

(57) ABSTRACT

Conventional retimers generally consume too much power, are too noisy, and are too large. Additionally, phase noise and jitter are generally a function of retiming. As a result, a retimer is provided with a smaller footprint that has reduced power consumption and improved noise characteristics over other conventional retimers.

### TECHNICAL FIELD

The invention relates generally to a retiming circuit or retimer and, more particularly, to a retimer for clock dividers.

### BACKGROUND

Referring to FIG. 1A of the drawings, reference numeral 100 generally designates a conventional divider. Divider 100 generally comprises a delay chain, counter 102, delay circuit 104, preconditioner 106, retimer 108, and driver 110. Generally, the delay chain is comprised of clock buffers 112 and 114 that receive a differential clock signal CLKIN and generate delayed, differential clock signals CLK1 and CLK2. Typically, buffers 112 and 114 isolate and sharpen the resistor-capacitor (RC) limited clock signal CLKIN, effectively, “cleaning up” the clock signal CLKIN. Buffers 112 and 114 each also introduce a delay.

In operation, these differential clock signals CLK1 and CLK2 are provided to the counter 102, delay circuit 104, preconditioner 106, and retimer 108 so that a divided clock signal CLKOUT can be output from driver 110. In particular, counter 102 (which can be reset by reset signal RST and which has a programmable division to divide clock signal CLKIN) receives clock signal CLK1, along with the delay circuit 104 and preconditioner 106. Retimer 108, on the other hand, receives clock signal CLK2. A reason for this particular arrangement is power conservation because it allows counter 102, delay circuit 104, and preconditioner 106 to be “sloppy.”

Turning to FIG. 1B, a more detailed diagram of preconditioner 106 and retimer 108 can be seen. Preconditioner 106 is generally comprised of logic 116 that receives data from delay circuit 104 and performs logical operations on the data and flip-flops 118 and 120 (which are clocked by clock signal CLK1 and the inverse of clock signal CLK1). Essentially, preconditioner 106 formulates data from delay circuit 104 to retimer 108 for 50% duty cycle and ½ cycle delay. Each of flip-flops 118 and 120 are coupled to flip-flops 122 and 124 of retimer 108, respectively. The flip-flops 122 and 124 are timed or clocked by clock signal CLK2 and the inverse of clock signal CLK2, respectively. OR gate 126 receives output from flip-flops 122 and 124 (so as to generate a 50% duty cycle, and multiplexer or mux 128 receives clock signal CLK2 and the signal from OR gate 126 to generate output signal OUT for driver 110. Essentially, the retimer 108 generates a clock counter output with a lower noise clock.

A problem with this arrangement, however, is that circuit 108 consumes too much power, is too noisy, and is too large. Generally speaking, phase noise and jitter are a function of retiming as is the power consumption. Thus, there is a need for a smaller circuit with lower power consumption and less noise.

Some other examples of conventional circuits are: U.S. Pat. No. 7,356,106; U.S. Patent Pre-Grant Publ. No. 2005/0135471; and PCT Publ. No. WO2008/132669.

### SUMMARY

A preferred embodiment of the present invention, accordingly, provides an apparatus. The apparatus comprises a preconditioner that receives a first differential clock signal and a data signal and that generates a first differential output signal and a second differential output signal; and a retimer having: a first output terminal; a second output terminal; a first differential input pair that is coupled to the first and second output terminals and that receives the first differential output signal; a second differential input pair that is coupled to the first and second output terminals and that receives the second differential output signal; a wired-OR gate that is coupled to each of the first and second differential pairs; and a pair of clock input transistors that is coupled to the first and second differential input pairs and that receives a second differential clock signal.

In accordance with a preferred embodiment of the present invention, each of the first and second differential pairs further comprises: a first bipolar transistor that is coupled to the wired-OR gate at its collector and that receives a first portion of one of the first and second differential output signals at its base; and a second bipolar transistor that is coupled to the wired-OR gate at its collector, that receives a second portion of one of the first and second differential output signals at its base, and that is coupled to the emitter of the first bipolar transistor at its emitter.

In accordance with a preferred embodiment of the present invention, the apparatus further comprises: a first clock buffer that receives an input clocks signal and that outputs the second differential clock signal; and a second clock buffer that is coupled to the first delay circuit and that outputs the first differential clock signal.

In accordance with a preferred embodiment of the present invention, the preconditioner further comprises: logic that receives the data signal; a first flip-flop that is coupled to the logic, that is receives the first differential clock signal, and that outputs the first differential output signal; and a second flip-flop that is coupled to the logic, that receives an inverse of the first differential clock signal, and that outputs the second differential output signal.

In accordance with a preferred embodiment of the present invention, the pair of clock input transistors further comprises: a third bipolar transistor that is coupled to the emitters of the first and second bipolar transistors of the first differential pair at its collector and that receives a first portion of the second differential clock signal at its base; and a fourth bipolar transistor that is coupled to the emitters of the first and second bipolar transistors of the second differential pair at its collector, that receives a second portion of the second differential clock signal at its base, and that is coupled to the emitter of the third bipolar transistor at its emitter.

In accordance with a preferred embodiment of the present invention, the apparatus further comprises a current source that is coupled to the emitters of the third and four bipolar transistors.

In accordance with a preferred embodiment of the present invention, the pair of clock input transistors further comprises: a third bipolar transistor that is coupled to the emitters of the first and second bipolar transistors of the first differential pair at its emitter and that receives a first portion of the second differential clock signal at its base; and a fourth bipolar transistor that is coupled to the emitters of the first and second bipolar transistors of the second differential pair at its emitter and that receives a second portion of the second differential clock signal at its base.

In accordance with a preferred embodiment of the present invention, the apparatus further comprises: a first current source that is coupled to the emitter of the third bipolar transistor; and a second current source that is coupled to the emitter of the fourth bipolar transistor.

In accordance with a preferred embodiment of the present invention, an apparatus is provided. The apparatus comprises a preconditioner that receives a first differential clock signal and a data signal and that generates a first differential output signal and a second differential output signal; and a retimer having: a first voltage rail; a second voltage rail; a wired-OR gate a first output terminal, and a second output terminal; a first resistor coupled between the first voltage rail and the first output terminal; a second resistor coupled between the first voltage rail and the second output terminal; a first bipolar transistor that is coupled to the wired-OR gate at its collector and that receives a first portion of the first differential output signal at its base; and a second bipolar transistor that is coupled to the wired-OR gate at its collector, that receives a second portion of the first differential output signal at its base, and that is coupled to the emitter of the first bipolar transistor at its emitter; a third bipolar transistor that is coupled to the wired-OR gate at its collector and that receives a first portion of the second differential output signal at its base; and a fourth bipolar transistor that is coupled to the wired-OR gate at its collector, that receives a second portion of the second differential output signal at its base, and that is coupled to the emitter of the first bipolar transistor at its emitter; and a pair of clock input transistors, wherein each transistors from the pair of clock input transistors is coupled to the emitter of one of the first, second, third, and fourth bipolar transistors differential that receives a second differential clock signal.

In accordance with a preferred embodiment of the present invention, each of the first, second, third, and fourth transistors is an NPN transistor.

In accordance with a preferred embodiment of the present invention, the pair of clock input transistors further comprises: a fifth bipolar transistor that is coupled to the emitters of the first and second bipolar transistors at its collector and that receives a first portion of the second differential clock signal at its base; and a sixth bipolar transistor that is coupled to the emitters of the third and fourth bipolar transistors at its collector, that receives a second portion of the second differential clock signal at its base, and that is coupled to the emitter of the fifth bipolar transistor at its emitter.

In accordance with a preferred embodiment of the present invention, the apparatus further comprises a current source that is coupled to the emitters of the fifth and sixth bipolar transistors.

In accordance with a preferred embodiment of the present invention, the pair of clock input transistors further comprises: a fifth bipolar transistor that is coupled to the emitters of the first and second bipolar transistors at its emitter and that receives a first portion of the second differential clock signal at its base; and a sixth bipolar transistor that is coupled to the emitters of the third and fourth bipolar transistors at its emitter and that receives a second portion of the second differential clock signal at its base.

In accordance with a preferred embodiment of the present invention, the apparatus further comprises: a first current source that is coupled to the emitter of the fifth bipolar transistor; and a second current source that is coupled to the emitter of the sixth bipolar transistor.

In accordance with a preferred embodiment of the present invention, an apparatus comprising: a delay chain that receives an input clock signal and that generates a plurality of differential clock signals; a counter having a programmable division and that is coupled to the delay chain to receive a first differential clock signal of the plurality of differential clock signals; a delay circuit that is coupled to the counter and that receives the first differential clock signal; a preconditioner that is coupled to the delay circuit, that receives the first differential clock signal, and that generates a first differential output signal and a second differential output signal, wherein the preconditioner includes: logic that receives the data signal; a first flip-flop that is coupled to the logic, that is receives the first differential clock signal, and that outputs the first differential output signal; and a second flip-flop that is coupled to the logic, that receives an inverse of the first differential clock signal, and that outputs the second differential output signal; a retimer having: a first voltage rail; a second voltage rail; a wired-OR gate a first output terminal, and a second output terminal; a first resistor coupled between the first voltage rail and the first output terminal; a second resistor coupled between the first voltage rail and the second output terminal; a first NPN transistor that is coupled to the wired-OR gate at its collector and that receives a first portion of the first differential output signal at its base; and a second NPN transistor that is coupled to the wired-OR gate at its collector, that receives a second portion of the first differential output signal at its base, and that is coupled to the emitter of the first bipolar transistor at its emitter; a third NPN transistor that is coupled to the wired-OR gate at its collector and that receives a first portion of the second differential output signal at its base; and a fourth NPN transistor that is coupled to the wired-OR gate at its collector, that receives a second portion of the second differential output signal at its base, and that is coupled to the emitter of the first bipolar transistor at its emitter; and a pair of clock input transistors, wherein each transistors from the pair of clock input transistors is coupled to the emitter of one of the first, second, third, and fourth bipolar transistors differential that receives a second differential clock signal; and a driver that is coupled to the first and second output terminals of the retimer so as to output a divided clock signal.

In accordance with a preferred embodiment of the present invention, the pair of clock input transistors further comprises: a fifth NPN transistor that is coupled to the emitters of the first and second NPN transistors at its collector and that receives a first portion of the second differential clock signal at its base; and a sixth bipolar transistor that is coupled to the emitters of the third and fourth NPN transistors at its collector, that receives a second portion of the second differential clock signal at its base, and that is coupled to the emitter of the fifth NPN transistor at its emitter.

In accordance with a preferred embodiment of the present invention, the apparatus further comprises a current source that is coupled to the emitters of the fifth and sixth NPN transistors.

In accordance with a preferred embodiment of the present invention, the pair of clock input transistors further comprises: a fifth NPN transistor that is coupled to the emitters of the first and second NPN transistors at its emitter and that receives a first portion of the second differential clock signal at its base; and a sixth NPN transistor that is coupled to the emitters of the third and fourth NPN transistors at its emitter and that receives a second portion of the second differential clock signal at its base.

In accordance with a preferred embodiment of the present invention, the apparatus further comprises: a first current source that is coupled to the emitter of the fifth NPN transistor; and a second current source that is coupled to the emitter of the sixth NPN transistor.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B are a block diagrams of a conventional divider;

FIG. 2A is a block diagram of a retimer and preconditioner in accordance with a preferred embodiment of the present invention; and

FIGS. 2B and 2C are circuit diagrams for the retimer of FIG. 2A.

### DETAILED DESCRIPTION

Refer now to the drawings wherein depicted elements are, for the sake of clarity, not necessarily shown to scale and wherein like or similar elements are designated by the same reference numeral through the several views.

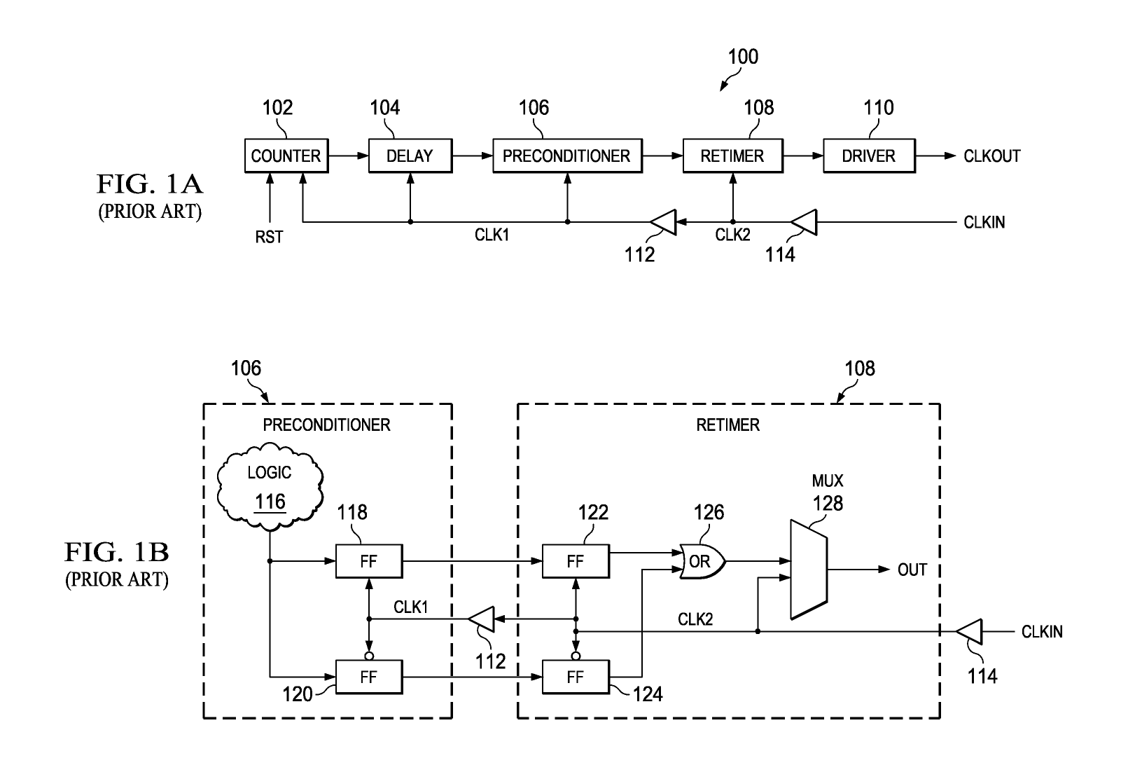

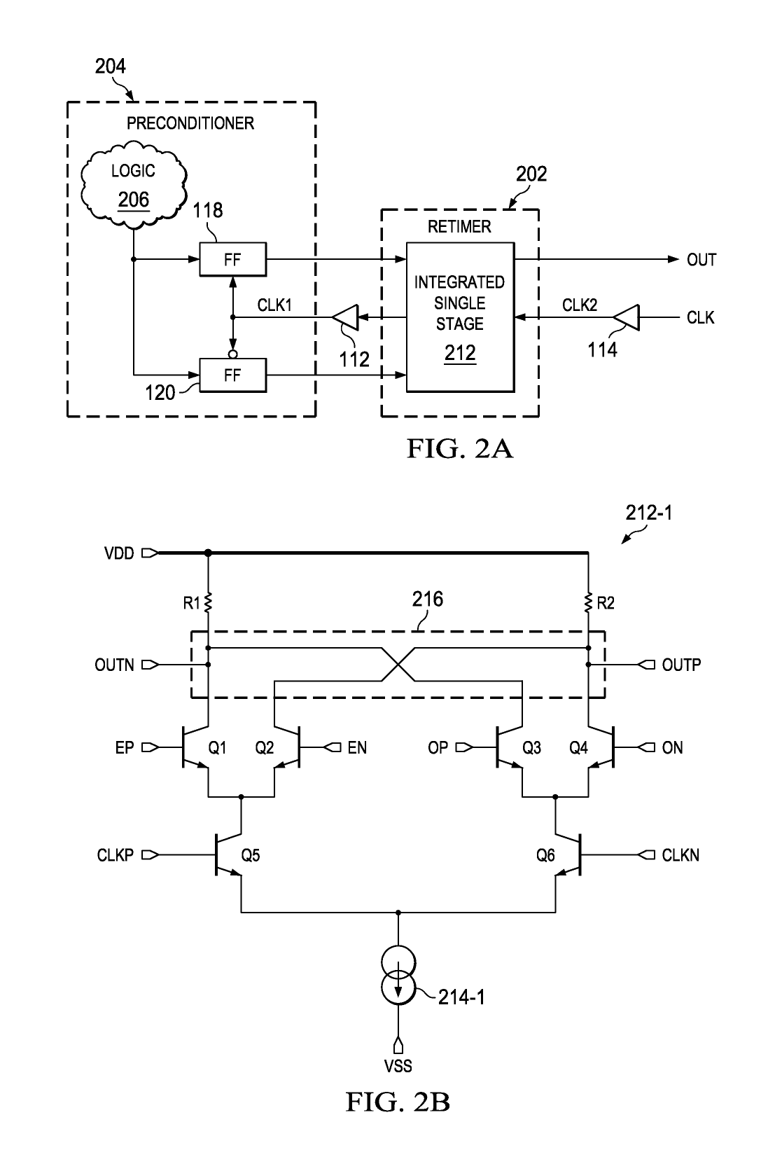

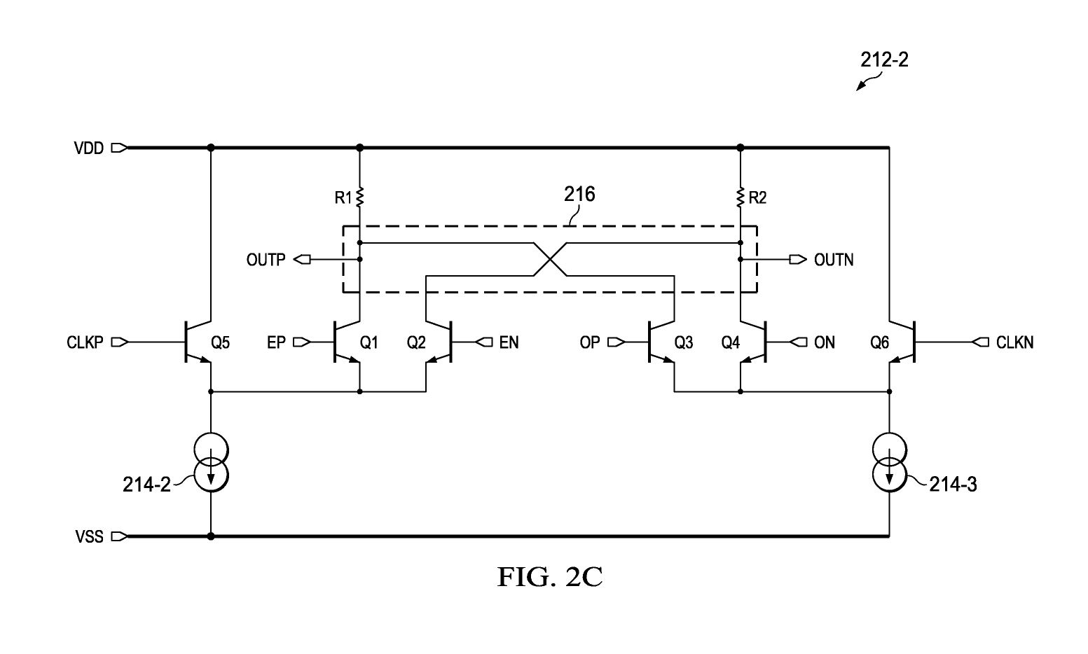

Turning to FIG. 2A, a retimer 202 and preconditioner 204 (which are intended to replace preconditioner 106 and retimer 108 of FIG. 1) in accordance with a preferred embodiment of the present invention can be seen. Retimer 202 is generally comprised of an integrated signal stage 212, while preconditioner 204 is generally the same as preconditioner 106, except that logic 116 has been replaced with logic 206. Logic 206 is mapped to operate with stage 212.

In FIG. 2B, an example of the stage 212 (which is referred to as 212-1 in FIG. 2B) can be seen in greater detail. Here, resistors R1 and R2 (which are each about 200Ω) are generally coupled between voltage rail VDD and output terminals OUTP and OUTN and cascoded differential pairs Q1/Q2, Q3/Q4, and Q5/Q6 (which are preferably NPN transistors) are generally coupled to the output terminals OUTP and OUTN. The differential pair Q1 and Q2 receives an “even” signal from flip-flop 118, and differential pair Q3 and Q4 receives an “odd” signal from flip-flop 120. Additionally, because each of these differential pairs Q1/Q2 and Q3/Q4 is coupled to both output terminals OUTP and OUTN, a wired-OR gate 216 is created. Clock signal CLK2 then is provided to the differential pair Q5/Q6 (which is coupled to each of the differential pairs Q1/Q2 and Q3/Q4). Additionally, current source 214-1 is coupled between the differential pair Q5/Q6 and voltage rail VSS (which is typically at ground).

In operation, the “even” and “odd” signals from flip-flops 118 and 120 may not be completely aligned, and stage 212 generally enables realigning or retiming. Assuming that terminals EP and ON are logic high (or “1”) and terminals OP and EN are logic low (or “0”), the output terminals OUTP and OUTN toggle with the clock signals CLK2 input into terminals CLKP and CLKN. Additionally, assuming that terminals EN and OP are high and terminals ON and EP are low, the output terminals OUTP and OUTN toggle with the clock signals CLK2 input into terminals CLKP and CLKN. Thus, retimer 202 enables retiming with a more compact arrangement and lower power consumption compared to conventional retimers (such as retimer 108).

Turning now to FIG. 2C, an example of the stage 212 (which is referred to as 212-2 in FIG. 2B) can be seen in greater detail. Stage 212-2 has a similar structure to stage 212-1, including many of the same components. Some difference between stages 212-1 and 212-2 are that current source 214-1 has been replaced by current sources 214-2 and 214-3 and that transistors Q5 and Q6 are arranged to be in parallel with differential pairs Q1/Q2 and Q3/Q4, respectively. This arrangement in stage 212-2 enables operation at a lower voltage compared to stage 212-1 with the same general functionality.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a preconditioner that receives a first differential clock signal and a data signal and that generates a first differential output signal and a second differential output signal; and
a retimer having:
a first output terminal;
a second output terminal;
a first differential input pair that is coupled to the first and second output terminals and that receives the first differential output signal;
a second differential input pair that is coupled to the first and second output terminals and that receives the second differential output signal;
a wired-OR gate that is coupled to each of the first and second differential pairs; and
a pair of clock input transistors that is coupled to the first and second differential input pairs and that receives a second differential clock signal.

2. The apparatus of claim 1, wherein each of the first and second differential pairs further comprises:
a first bipolar transistor that is coupled to the wired-OR gate at its collector and that receives a first portion of one of the first and second differential output signals at its base; and
a second bipolar transistor that is coupled to the wired-OR gate at its collector, that receives a second portion of one of the first and second differential output signals at its base, and that is coupled to the emitter of the first bipolar transistor at its emitter.

3. The apparatus of claim 2, wherein the apparatus further comprises:
a first clock buffer that receives an input clocks signal and that outputs the second differential clock signal; and
a second clock buffer that is coupled to the first delay circuit and that outputs the first differential clock signal.

4. The apparatus of claim 3, wherein the preconditioner further comprises:
logic that receives the data signal;
a first flip-flop that is coupled to the logic, that is receives the first differential clock signal, and that outputs the first differential output signal; and
a second flip-flop that is coupled to the logic, that receives an inverse of the first differential clock signal, and that outputs the second differential output signal.

5. The apparatus of claim 2, wherein the pair of clock input transistors further comprises:
a third bipolar transistor that is coupled to the emitters of the first and second bipolar transistors of the first differential pair at its collector and that receives a first portion of the second differential clock signal at its base; and
a fourth bipolar transistor that is coupled to the emitters of the first and second bipolar transistors of the second differential pair at its collector, that receives a second portion of the second differential clock signal at its base, and that is coupled to the emitter of the third bipolar transistor at its emitter.

6. The apparatus of claim 5, wherein the apparatus further comprises a current source that is coupled to the emitters of the third and four bipolar transistors.

7. The apparatus of claim 2, wherein the pair of clock input transistors further comprises:
a third bipolar transistor that is coupled to the emitters of the first and second bipolar transistors of the first differential pair at its emitter and that receives a first portion of the second differential clock signal at its base; and
a fourth bipolar transistor that is coupled to the emitters of the first and second bipolar transistors of the second differential pair at its emitter and that receives a second portion of the second differential clock signal at its base.

8. The apparatus of claim 7, wherein the apparatus further comprises:
a first current source that is coupled to the emitter of the third bipolar transistor; and
a second current source that is coupled to the emitter of the fourth bipolar transistor.

9. An apparatus comprising:
a preconditioner that receives a first differential clock signal and a data signal and that generates a first differential output signal and a second differential output signal; and
a retimer having:
a first voltage rail;
a second voltage rail;
a wired-OR gate a first output terminal, and a second output terminal;
a first resistor coupled between the first voltage rail and the first output terminal;
a second resistor coupled between the first voltage rail and the second output terminal;
a first bipolar transistor that is coupled to the wired-OR gate at its collector and that receives a first portion of the first differential output signal at its base; and
a second bipolar transistor that is coupled to the wired-OR gate at its collector, that receives a second portion of the first differential output signal at its base, and that is coupled to the emitter of the first bipolar transistor at its emitter;
a third bipolar transistor that is coupled to the wired-OR gate at its collector and that receives a first portion of the second differential output signal at its base; and
a fourth bipolar transistor that is coupled to the wired-OR gate at its collector, that receives a second portion of the second differential output signal at its base, and that is coupled to the emitter of the first bipolar transistor at its emitter; and
a pair of clock input transistors, wherein each transistors from the pair of clock input transistors is coupled to the emitter of one of the first, second, third, and fourth bipolar transistors differential that receives a second differential clock signal.

10. The apparatus of claim 9, wherein the apparatus further comprises:
a first clock buffer that receives an input clocks signal and that outputs the second differential clock signal; and
a second clock buffer that is coupled to the first delay circuit and that outputs the first differential clock signal.

11. The apparatus of claim 10, wherein the preconditioner further comprises:
logic that receives the data signal;
a first flip-flop that is coupled to the logic, that is receives the first differential clock signal, and that outputs the first differential output signal; and
a second flip-flop that is coupled to the logic, that receives an inverse of the first differential clock signal, and that outputs the second differential output signal.

12. The apparatus of claim 9, wherein each of the first, second, third, and fourth transistors is an NPN transistor.

13. The apparatus of claim 9, wherein the pair of clock input transistors further comprises:
a fifth bipolar transistor that is coupled to the emitters of the first and second bipolar transistors at its collector and that receives a first portion of the second differential clock signal at its base; and
a sixth bipolar transistor that is coupled to the emitters of the third and fourth bipolar transistors at its collector, that receives a second portion of the second differential clock signal at its base, and that is coupled to the emitter of the fifth bipolar transistor at its emitter.

14. The apparatus of claim 13, wherein the apparatus further comprises a current source that is coupled to the emitters of the fifth and sixth bipolar transistors.

15. The apparatus of claim 9, wherein the pair of clock input transistors further comprises:
a fifth bipolar transistor that is coupled to the emitters of the first and second bipolar transistors at its emitter and that receives a first portion of the second differential clock signal at its base; and
a sixth bipolar transistor that is coupled to the emitters of the third and fourth bipolar transistors at its emitter and that receives a second portion of the second differential clock signal at its base.

16. The apparatus of claim 15, wherein the apparatus further comprises:
a first current source that is coupled to the emitter of the fifth bipolar transistor; and
a second current source that is coupled to the emitter of the sixth bipolar transistor.

17. An apparatus comprising:
a delay chain that receives an input clock signal and that generates a plurality of differential clock signals;
a counter having a programmable division and that is coupled to the delay chain to receive a first differential clock signal of the plurality of differential clock signals;
a delay circuit that is coupled to the counter and that receives the first differential clock signal;
a preconditioner that is coupled to the delay circuit, that receives the first differential clock signal, and that generates a first differential output signal and a second differential output signal, wherein the preconditioner includes:
logic that receives the data signal;
a first flip-flop that is coupled to the logic, that is receives the first differential clock signal, and that outputs the first differential output signal; and
a second flip-flop that is coupled to the logic, that receives an inverse of the first differential clock signal, and that outputs the second differential output signal;
a retimer having:
a first voltage rail;
a second voltage rail;
a wired-OR gate a first output terminal, and a second output terminal;
a first resistor coupled between the first voltage rail and the first output terminal;
a second resistor coupled between the first voltage rail and the second output terminal;
a first NPN transistor that is coupled to the wired-OR gate at its collector and that receives a first portion of the first differential output signal at its base; and
a second NPN transistor that is coupled to the wired-OR gate at its collector, that receives a second portion of the first differential output signal at its base, and that is coupled to the emitter of the first bipolar transistor at its emitter;
a third NPN transistor that is coupled to the wired-OR gate at its collector and that receives a first portion of the second differential output signal at its base; and
a fourth NPN transistor that is coupled to the wired-OR gate at its collector, that receives a second portion of the second differential output signal at its base, and that is coupled to the emitter of the first bipolar transistor at its emitter; and
a pair of clock input transistors, wherein each transistors from the pair of clock input transistors is coupled to the emitter of one of the first, second, third, and fourth bipolar transistors differential that receives a second differential clock signal; and
a driver that is coupled to the first and second output terminals of the retimer so as to output a divided clock signal.

18. The apparatus of claim 17, wherein the pair of clock input transistors further comprises:
a fifth NPN transistor that is coupled to the emitters of the first and second NPN transistors at its collector and that receives a first portion of the second differential clock signal at its base; and
a sixth bipolar transistor that is coupled to the emitters of the third and fourth NPN transistors at its collector, that receives a second portion of the second differential clock signal at its base, and that is coupled to the emitter of the fifth NPN transistor at its emitter.

19. The apparatus of claim 18, wherein the apparatus further comprises a current source that is coupled to the emitters of the fifth and sixth NPN transistors.

20. The apparatus of claim 17, wherein the pair of clock input transistors further comprises:
a fifth NPN transistor that is coupled to the emitters of the first and second NPN transistors at its emitter and that receives a first portion of the second differential clock signal at its base; and
a sixth NPN transistor that is coupled to the emitters of the third and fourth NPN transistors at its emitter and that receives a second portion of the second differential clock signal at its base.

21. The apparatus of claim 20, wherein the apparatus further comprises:
a first current source that is coupled to the emitter of the fifth NPN transistor; and
a second current source that is coupled to the emitter of the sixth NPN transistor.
